(19) United States
(12) Patent Application Publication
(10) Pub. No.: US 2025/0125299 A1
(43) Pub. Date: Apr. 17, 2025

(54) SEMICONDUCTOR PACKAGE

(71) Applicant: Samsung Electronics Co., Ltd., Suwon-si (KR)

(72) Inventor: Do Hoon Kim, Suwon-si (KR)

(21) Appl. No.: 18/772,412

(22) Filed: Jul. 15, 2024

(30) Foreign Application Priority Data
Oct. 16, 2023 (KR) 10-2023-0137866
Oct. 27, 2023 (KR) 10-2023-0145398

(51) Int. Cl. H01L 23/00; H01L 23/31; H01L 23/538; H01L 25/065; H10B 80/00

(52) U.S. Cl. CPC H01L 24/32; H01L 23/5383; H01L 24/16; H01L 24/73; H01L 25/0652; H01L 23/3107; H01L 24/33; H01L 24/48; H01L 2224/16227; H01L 2224/26175; H01L 2224/32145; H01L 2224/32225; H01L 2224/33181; H01L 2224/48227; H01L 2224/73204; H01L 2224/73265; H01L 2225/0651; H10B 80/00

(57) ABSTRACT

Disclosed is a semiconductor package including: a substrate including first and second surfaces opposite to each other, wherein the substrate extends in first and second directions intersecting each other; a first semiconductor chip on the first surface of the substrate; a second semiconductor chip on the first surface of the substrate and spaced apart from the first semiconductor chip in the first direction; and a dam structure at least partially surrounding the first semiconductor chip, wherein the dam structure includes first and second dam structures on the first surface of the substrate and spaced apart from each other in the first direction such that the first semiconductor chip resides therebetween, wherein the first and second dam structures have different heights relative to the first surface of the substrate.

### CROSS-REFERENCE TO RELATED APPLICATIONS

This application claims priority from Korean Patent Applications No. 10-2023-0137866 filed on Oct. 16, 2023 and No. 10-2023-0145398 filed on Oct. 27, 2023 in the Korean Intellectual Property Office, and all the benefits accruing therefrom under 35 U.S.C. 119, the contents of which in its entirety are herein incorporated by reference.

### BACKGROUND

The present disclosure relates to a semiconductor package.

For high level integration and high-performance operation of a semiconductor device, stacking semiconductor chips has been proposed. For example, a multi-chip package in which a plurality of chips is mounted in a single semiconductor package, or a system-in package in which stacked different types of chips operate as a single system are being proposed.

To electrically connect the stacked semiconductor chips to each other, a wire bonding or flip chip bonding scheme may be used. The flip chip bonding scheme refers to a packaging scheme that electrically connects a semiconductor chip and a semiconductor chip pad to each other via a bump. The wire bonding scheme refers to a packaging scheme that uses a wire.

In some instances, an underfill material formed between the semiconductor chip and a substrate may overflow, resulting in defective characteristics.

### SUMMARY

A technical purpose to be achieved by the present disclosure is to provide a semiconductor package in which the above-identified defective characteristics are removed.

Embodiments according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A semiconductor package according to some embodiments of the present disclosure includes a substrate including first and second surfaces opposite to each other, wherein the substrate extends in first and second directions intersecting each other; a first semiconductor chip on the first surface of the substrate; a second semiconductor chip on the first surface of the substrate and spaced apart from the first semiconductor chip in the first direction; and a dam structure at least partially surrounding the first semiconductor chip, wherein the dam structure includes first and second dam structures on the first surface of the substrate and spaced apart from each other in the first direction such that the first semiconductor chip resides therebetween, wherein the first and second dam structures have different heights relative to the first surface of the substrate.

A semiconductor package according to some embodiments of the present disclosure includes a substrate including first and second surfaces opposite to each other, wherein the substrate extends in first and second directions intersecting each other; a semiconductor chip on the first surface of the substrate; a semiconductor chip stack including a plurality of semiconductor chips on the first surface of the substrate, wherein the semiconductor chip stack is spaced apart from the semiconductor chip in the first direction; a bump electrically connecting the substrate and the semiconductor chip to each other; a bonding wire electrically connecting the substrate and the semiconductor chip stack to each other; and a dam structure on the first surface of the substrate, wherein the dam structure includes portions spaced apart from each other, wherein a height of a second portion of the dam structure on a central area of the substrate adjacent to the bonding wire is greater than a height of a first portion of the dam structure on a peripheral area of the substrate.

A semiconductor package according to some embodiments of the present disclosure includes a substrate including first and second surfaces opposite to each other, wherein a first trench extends into a portion of the substrate from the first surface; a semiconductor chip on the first surface of the substrate; a semiconductor chip stack including a plurality of semiconductor chips on the first surface of the substrate, wherein the semiconductor chip stack is spaced apart from the semiconductor chip; a bump electrically connecting the substrate and the semiconductor chip to each other; a bonding wire electrically connecting the substrate and the semiconductor chip stack to each other; a dam structure on the first surface of the substrate, wherein the dam structure includes portions spaced apart from each other; and an underfill material layer extending between the first surface of the substrate and the semiconductor chip, and extending in the first trench.

Specific details of other embodiments are included in the detailed description and drawings.

### BRIEF DESCRIPTION OF DRAWINGS

The above and other aspects and features of the present disclosure will become more apparent by describing in detail some embodiments thereof with reference to the attached drawings, in which:

FIG. 1 is an example layout diagram illustrating a semiconductor package according to embodiments of the present disclosure;

FIG. 2 is a cross-sectional view of the semiconductor package taken along a line I-I′ in FIG. 1;

FIG. 3 is an example layout diagram illustrating a semiconductor package according to embodiments of the present disclosure;

FIG. 4 is a cross-sectional view of the semiconductor package taken along a line II-II′ in FIG. 3;

FIG. 5 to FIG. 8 are enlarged diagrams of an area R of the semiconductor package in FIG. 4;

FIG. 9 is an example layout diagram illustrating a semiconductor package according to embodiments of the present disclosure;

FIG. 10 is a cross-sectional view of the semiconductor package taken along a line III-III′ in FIG. 9; and

FIG. 11 to FIG. 15 are example layout diagrams illustrating a semiconductor package according to embodiments of the present disclosure.

### DETAILED DESCRIPTION

Advantages and features of the present disclosure, and a method of achieving the advantages and features will become apparent with reference to embodiments described below in detail together with the accompanying drawings. However, embodiments of the present disclosure are not limited to the embodiments as disclosed herein, but may be implemented in various different forms. Thus, these embodiments are set forth only to make the present disclosure, and to inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings of the present disclosure are illustrative, and embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will also be understood that when a first element or layer is referred to as being present “on” a second element or layer, the first element may be disposed directly on the second element or may be disposed indirectly on the second element with a third element or layer being disposed between the first and second elements or layers. It will also be understood that when a first element or layer is referred to as being present “under” a second element or layer, the first element may be disposed directly under the second element or may be disposed indirectly under the second element with a third element or layer being disposed between the first and second elements or layers.

It will be understood that when an element or layer is referred to as being “connected to”, or “coupled to” another element or layer, it may be directly connected to or coupled to another element or layer, or one or more intervening elements or layers therebetween may be present. In addition, it will also be understood that when an element or layer is referred to as being “between” two elements or layers, it may be the only element or layer between the two elements or layers, or one or more intervening elements or layers therebetween may also be present.

In addition, it will also be understood that when an element or layer is referred to as being “between” two elements or layers, it may be the only element or layer between the two elements or layers, or one or more intervening elements or layers therebetween may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments”, “examples”, “aspects”, and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

As used herein, an element or region that is “covering” or “surrounding” or “filling” another element or region may completely or partially cover or surround or fill the other element or region.

The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Description.

Hereinafter, embodiments of the present disclosure are described in detail with reference to the attached drawings.

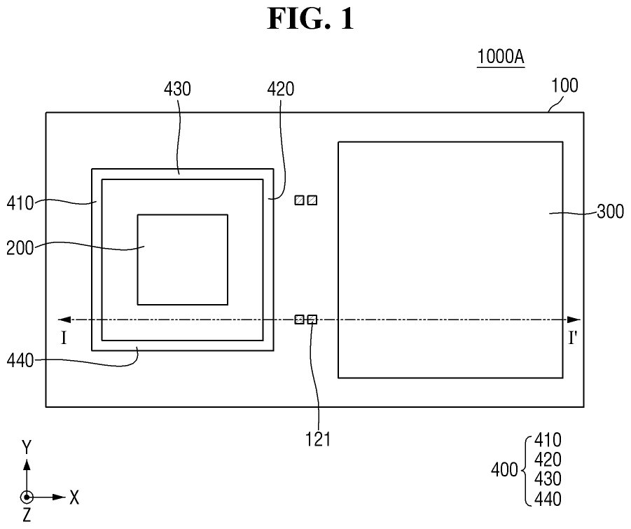

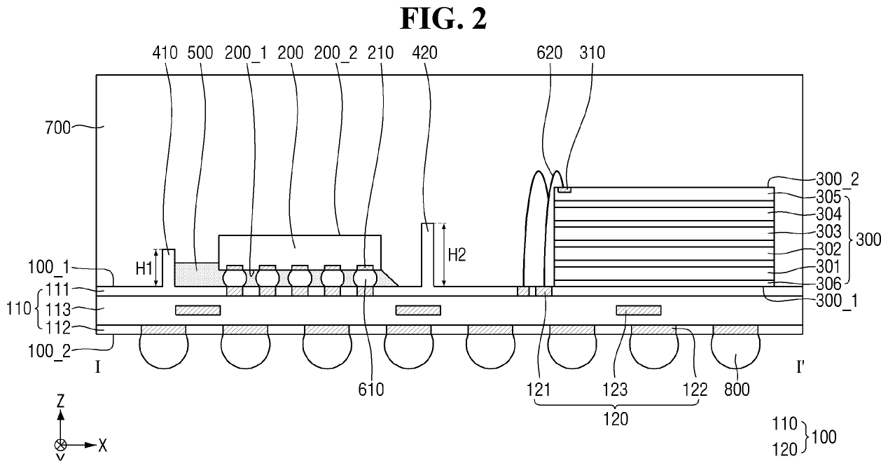

FIG. 1 is an example layout diagram illustrating a semiconductor package according to some embodiments of the present disclosure. FIG. 2 is a cross-sectional view of the semiconductor package taken along the line I-I′ in FIG. 1.

Referring to FIG. 1 and FIG. 2, a semiconductor package according to some embodiments of the present disclosure includes a substrate 100, a first semiconductor chip 200, a second semiconductor chip 300, a dam structure 400, and an underfill material layer 500, and may further include a mold layer 700.

The substrate 100 may include an insulating layer 110 including a first protective film 111, a second protective film 112, an insulating film 113, and a wiring layer 120. The wiring layer 120 may include a plurality of wirings 121, 122, and 123.

The substrate 100 may include a first surface 100_1 and a second surface 100_2 that oppose each other. The first surface 100_1 of the substrate 100 may mean an upper surface of the substrate 100, and the second surface 100_2 of the substrate 100 may mean a lower surface of the substrate 100, for example, when the substrate 100 defines a base reference plane.

The first surface 100_1 of the substrate 100 may extend in a first direction X and a second direction Y intersecting each other. The first direction X and the second direction Y may intersect each other perpendicularly. A third direction Z may mean a direction perpendicular to a plane including the first direction X and the second direction Y. In some embodiments, the first and second semiconductor chips 200 and 300 may be stacked in the third direction Z on the first surface 100_1 of the substrate 100.

A plurality of external connection terminals 800 may be disposed on the second surface 100_2 of the substrate 100. The wiring layer 120 may include multiple wirings 121, 122, and 123 to electrically connect the first and second semiconductor chips 200 and 300 and the external connection terminal 800 to each other.

The external connection terminal 800 may be, for example, spherical or elliptical in shape. However, embodiments of the present disclosure are not limited thereto. The external connection terminal 800 may include at least one of, for example, tin (Sn), indium (In), lead (Pb), zinc (Zn), nickel (Ni), gold (Au), silver (Ag), copper (Cu), antimony (Sb), bismuth (Bi) or combinations thereof. However, the technical idea of the present disclosure is not limited thereto.

The external connection terminal 800 may electrically connect the substrate 100 to an external device. Accordingly, the external connection terminal 800 may provide an electrical signal to the substrate 100, or may provide an electrical signal from the substrate 100 to the external device.

The substrate 100 may include, for example, a printed circuit board (PCB), or a ceramic substrate. However, the technical idea of the present disclosure is not limited thereto. When the substrate 100 includes the printed circuit board, the insulating film 113 may be made of at least one material selected from phenol resin, epoxy resin, and polyimide. For example, the insulating film 113 may include at least one material selected from ABF (Ajinomoto Build-up Film), FR-4, tetrafunctional epoxy, polyphenylene ether, epoxy/polyphenylene oxide, bismaleimide triazine (BT), thermount, cyanate ester, polyimide, and liquid crystal polymer.

Each of the first protective film 111 and the second protective film 112 may be solder resist. Each of the first protective film 111 and the second protective film 112 may include, for example, PID (photoimageable dielectric). However, embodiments of the present disclosure are not limited thereto.

A first surface of the insulating film 113 may be at least partially covered with the first protective film 111, and at least a portion of the first wiring 121 may not be covered with the first protective film 111 so as to be exposed (i.e., not covered with the first protective film 111). The exposed portion of the first wiring 121 serves as a pad. Thus, the exposed portion of the first wiring 121 and a pad 310 of the second semiconductor chip 300 may be electrically connected to each other via a bonding wire 620.

A second opposing surface of the insulating film 113 may be at least partially covered with the second protective film 112, and at least a portion of the second wiring 122 may not be covered with the second protective film 112 so as to be exposed (i.e., not covered with the second protective film 112). The exposed portion of the second wiring 122 may be directly connected to the external connection terminal 800.

The wiring layer 120 may be composed of multiple layers. The plurality of wirings 121, 122, and 123 may be respectively formed in three layers, for example. However, embodiments of the present disclosure are not limited thereto. For example, the wiring layer 120 may include wirings respectively disposed in two layers or at least four layers.

Although not specifically shown, the wiring layer 120 may further include a plurality of vias for electrically connecting the plurality of wirings 121, 122, and 123 to each other.

The wiring layer 120 may include, for example, a conductive material. For example, the wiring layer 120 may include at least one metal selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or an alloy of at least two thereof.

The first semiconductor chip 200 may be disposed on the first surface 100_1 of the substrate 100. The first semiconductor chip 200 may be disposed on the first protective film 111. The first semiconductor chip 200 may include a first surface 200_1 and an opposing second surface 200_2. The first surface 200_1 of the first semiconductor chip 200 may refer to an active surface electrically connected to the substrate 100.

For example, the first semiconductor chip 200 may be a volatile memory chip, such as dynamic random access memory (DRAM) or Static RAM (SRAM), or a non-volatile memory chip, such as phase-change RAM (PRAM), magneto resistive RAM (MRAM), ferroelectric RAM (FeRAM), or resistive RAM (RRAM). Alternatively, the first semiconductor chip 200 may be an HBM (High Bandwidth Memory) chip in which multiple DRAM memory chips are stacked. However, the technical idea of the present disclosure is not limited thereto.

The first semiconductor chip 200 may be electrically connected to the substrate 100 via a bump 610 residing between the first semiconductor chip 200 and the substrate 100. The first semiconductor chip 200 may be mounted on the substrate 100 in the flip chip bonding scheme.

The bump 610 may connect a pad 210 of the first semiconductor chip 200 and the substrate 100 to each other. For example, the bump 610 may contact at least a portion of the first wiring 121 of the substrate 100. The bump 610 may be, for example, spherical or elliptical in shape. However, embodiments of the present disclosure are not limited thereto. The bump 610 may include, for example, tin (Sn), indium (In), bismuth (Bi), antimony (Sb), copper (Cu), silver (Ag), zinc (Zn), lead (Pb), or combinations thereof. However, embodiments of the present disclosure are not limited thereto.

The pad 210 of the first semiconductor chip 200 may be disposed on the first surface 200_1 of the first semiconductor chip 200. For example, the pad 210 may include, but is not limited to, copper (Cu), copper alloy, nickel (Ni), palladium (Pd), platinum (Pt), gold (Au), cobalt (Co), or combinations thereof.

The second semiconductor chip 300 may be disposed on the first surface 100_1 of the substrate 100, and may be spaced apart from the first semiconductor chip 200 in the first direction X (e.g., in a horizontal direction). The second semiconductor chip 300 may include a first surface 300_1 and an opposing second surface 300_2. The second semiconductor chip 300 may be electrically connected to the substrate 100 via a pad 310 on the second surface 300_2 of the second semiconductor chip 300.

The second semiconductor chip 300 may include a plurality of semiconductor chips 301 to 305 stacked in the third direction Z (e.g., in a vertical direction). Each of the semiconductor chips 301 to 305 may include a memory chip. Each of the semiconductor chips 301 to 305 may include, for example, a non-volatile memory chip such as NAND flash memory.

An adhesive layer 306 may reside between adjacent semiconductor chips 301 to 305. The adhesive layer 306 may be, for example, DAF (Direct Adhesive Film) or FOW (Film Over Wire). The adhesive layer 306 may include an insulating polymer. For example, the adhesive layer 306 may include epoxy-based resin and a filler.

For example, the filler may include at least one selected from a group consisting of silica (SiO₂), alumina (Al₂O₃), silicon carbide (SiC), barium sulfate (BaSO₄), talc, clay, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃). However, the material of the filler is not limited thereto, and the filler may include a metal material and/or an organic material.

The adhesive layer 306 may serve to electrically insulate adjacent semiconductor chips 301 to 305 from each other. Furthermore, the adhesive layer 306 may serve to electrically insulate, for example, one of the semiconductor chips 301 to 305 and the substrate 100 from each other.

Although not specifically shown, a controller may be provided on the substrate 100. The controller may be, for example, a logic chip that controls the memory chip.

Unlike what is shown, the semiconductor chips 301 to 305 included in the second semiconductor chip 300 may be stacked in a stepped manner. In this case, the second semiconductor chip 300 may have a stepped structure in which lengths along the first direction X of the semiconductor chips 301 to 305 sequentially increase or decrease in this order.

For example, one of the semiconductor chip 301 to 305 (e.g., semiconductor chip 301) may be stacked on another semiconductor chip 302 such that side ends thereof are spaced from each other by a certain distance in a specific direction. That is, side ends of the semiconductor chips 301 to 305 may be not aligned with each other in a vertical direction (i.e., the third direction Z) and thus may be offset relative to each other. The specific direction may be, for example, the first direction X and/or the second direction Y.

As the semiconductor chips 301 to 305 are stacked in the stepwise manner, the pad 310 may reside on an upper surface of each of the semiconductor chips 301 to 305, and may be exposed (i.e., not covered by an adjacent semiconductor chip 301 to 305).

The pad 310 of the second semiconductor chip 300 may include at least one metal selected from copper (Cu), aluminum (Al), tungsten (W), and titanium (Ti).

Unlike what is shown, at least a portion of the pad 310 of the second semiconductor chip 300 may extend upwardly beyond the second surface 300_2 of the second semiconductor chip 300.

The dam structure 400 may be disposed on the first surface 100_1 of the substrate 100. The dam structure 400 may be reside in an area on the first surface 100_1 proximate to the first semiconductor chip 200. The dam structure 400 may be reside between the first semiconductor chip 200 and the second semiconductor chip 300.

In a plan view, the dam structure 400 may be disposed to at least partially surround the first semiconductor chip 200. In a plan view, the dam structure 400 may include first and second dam structures 410 and 420 which extend in the second direction Y, and reside in the area proximate to the first semiconductor chip 200, and are arranged so as to face each other in the first direction X. The first dam structure 410 may reside in a peripheral area of the substrate 100. The second dam structure 420 may reside in a central area of the substrate 100. A spacing between the second dam structure 420 and the first semiconductor chip 200 may be less than a spacing between the bonding wire 620 and the first semiconductor chip 200.

The dam structure 400 may include third and fourth dam structures 430 and 440 connecting the first and second dam structures 410 and 420 to each other. The third and fourth dam structures 430 and 440 may extend in the first direction X and may be arranged so as to face each other in the second direction Y, and may reside in an area proximate to the first semiconductor chip 200. In other words, the first, second, third, and fourth dam structures 410 to 440 may be arranged to surround the first semiconductor chip 200.

In a cross-sectional view, the first and second dam structures 410 and 420 may be disposed on the first surface 100_1 of the substrate and may be arranged so as to be spaced apart from each other while the first semiconductor chip 200 resides therebetween. The first and second dam structures 410 and 420 may have different heights in the third direction Z (e.g., vertical direction) from the first surface 100_1 of the substrate 100.

For example, with the first substrate 100 defining a base reference plane, in some embodiments, the first dam structure 410 may have a first height H1 relative to the first surface 100_1 of the substrate 100, and the second dam structure 420 may have a second height H2 relative to the first surface 100_1 of the substrate 100 which is greater than the first height H1. In other words, the dam structure 400 may be constructed such that a height thereof on the central area of the substrate 100 adjacent to the bonding wire 620 is greater than a height thereof on the peripheral area of the substrate 100.

The dam structure 400 may be formed integrally with the substrate 100. The first and second dam structures 410 and 420 may be formed integrally with the first protective film 111. In this case, the first and second dam structures 410 and 420 may include the same insulating material as that of the first protective film 111.

The underfill material layer 500 may be formed on the substrate 100. The underfill material layer 500 may reside between the first surface 100_1 of the substrate 100 and the first semiconductor chip 200. The underfill material layer 500 may reside between the first and second dam structures 410 and 420. The underfill material layer 500 may be in direct contact with the first dam structure 410 and may be spaced apart from the second dam structure 420.

The underfill material layer 500 may fix the first semiconductor chip 200 onto the substrate 100 to prevent the first semiconductor chip 200 from breaking. The underfill material layer 500 may at least partially cover a side of the bump 610. The bump 610 may extend through the underfill material layer 500 so as to electrically connect the substrate 100 and the first semiconductor chip 200 to each other.

The underfill material layer 500 may include, for example, an insulating polymer material such as EMC (epoxy molding compound). However, embodiments of the present disclosure are not limited thereto. In some embodiments, the underfill material layer 500 may include a different material than that of the mold layer 700 described below. For example, the underfill material layer 500 may include an insulating material having a fluidity greater than that of the material of the mold layer 700. Accordingly, the underfill material layer 500 may efficiently fill a narrow space between the substrate 100 and the first semiconductor chip 200. In this way, the underfill material layer 500 is formed on the substrate 100 and is made of the material having good fluidity as described above. Thus, a shape of the underfill material layer 500 is not limited to a shape as shown in this drawing.

According to some embodiments, first and second dam structures 410 and 420 having different shapes may be formed on the substrate 100 to prevent the underfill material layer 500 from overflowing. Forming the first dam structure 410 may prevent the underfill material layer 500 from being exposed outside of the semiconductor package. Furthermore, forming the second dam structure 420 with the greater height may prevent the underfill material layer 500 from overflowing toward the area where the bonding wire 620 is formed. Accordingly, contamination of the first wiring 121 and a lower portion of the second semiconductor chip 300 may be prevented.

The mold layer 700 may be formed on the substrate 100 so as to at least partially cover the first and second semiconductor chips 200 and 300. The mold layer 700 may at least partially cover a side surface and an upper surface of the dam structure 400.

The mold layer 700 may include, for example, an insulating polymer material such as EMC (epoxy molding compound). The mold layer 700 may include a thermosetting resin such as an epoxy resin, a thermoplastic resin such as polyimide, or a resin containing a reinforcing material such as a filler in addition thereto, such as ABF, FR-4, and BT resin.

For example, the filler may include at least one selected from a group consisting of silica (SiO₂), alumina (Al₂O₃), silicon carbide (SiC), barium sulfate (BaSO₄), talc, clay, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃). However, the material of the filler is not limited thereto.

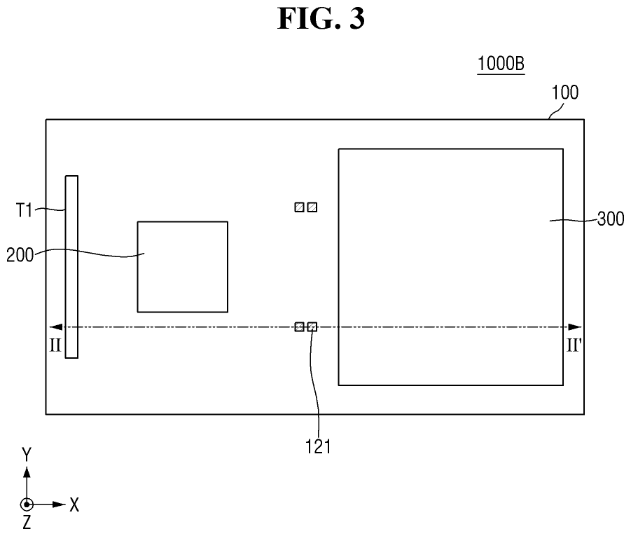

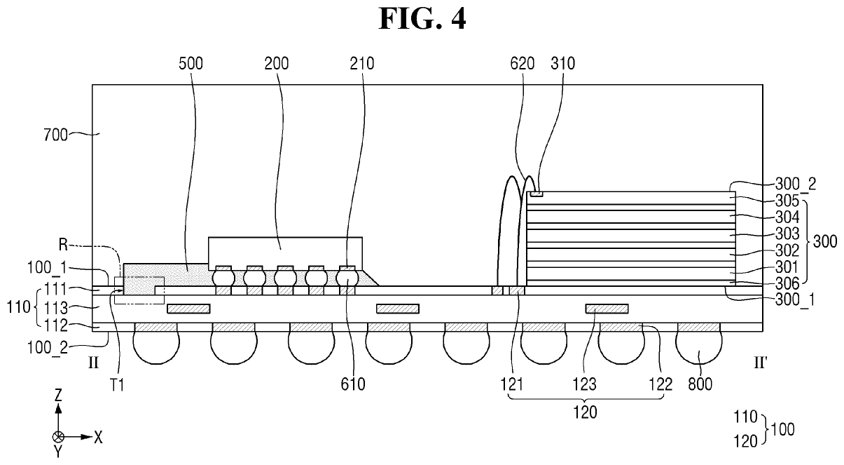

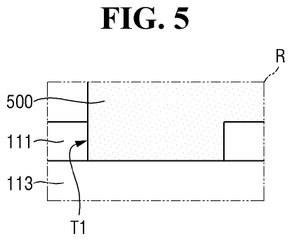

FIG. 3 is an example layout diagram illustrating a semiconductor package according to some embodiments of the present disclosure. FIG. 4 is a cross-sectional view of the semiconductor package taken along the line II-II′ in FIG. 3. FIG. 5 to FIG. 8 are enlarged drawings of the area R of the semiconductor package in FIG. 4. For convenience of description, following descriptions focus on differences thereof from the semiconductor package as described above using FIG. 1 to FIG. 2.

Referring to FIG. 3 to FIG. 5, a first trench T1 may be formed in the peripheral area of the substrate 100 spaced apart from the bonding wire 620. In the third direction Z, the first trench T1 may extend from the first surface 100_1 of the substrate 100 into at least a portion of the substrate 100. The underfill material layer 500 may be disposed within the first trench T1. The underfill material layer 500 may be received in at least a portion of the first protective film 111.

According to some embodiments, forming the first trench T1 in the substrate 100 may help guide the underfill material layer 500 into the first trench T1. Accordingly, overflow of the underfill material layer 500 may be controlled more effectively. In other words, forming the first trench T1 may help prevent the underfill material layer 500 from being exposed outside of the semiconductor package.

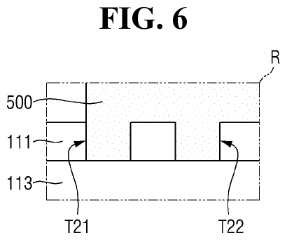

Referring to FIG. 6, in some embodiments, a plurality of trenches extending into at least a portion of the substrate 100 may be formed. Specifically, a second-first trench T21 and a second-second trench T22 extending into at least a portion of the substrate 100 may be formed. The second-first trench T21 and the second-second trench T22 may be spaced apart from each other (e.g., in a horizontal direction). The underfill material layer 500 may reside within each of the second-first trench T21 and the second-second trench T22.

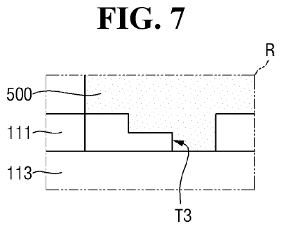

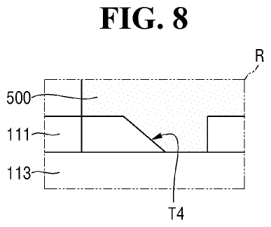

Referring to FIG. 7 and FIG. 8, a depth of the trench extending into at least a portion of the substrate 100 may increase in a stepwise manner or gradually as the trench approaches the center area of the substrate 100 adjacent to the bonding wire 620.

Referring to FIG. 7, a depth in the third direction Z of a third trench T3 may increase in a stepwise manner as the third trench extends toward the center area of the substrate 100 adjacent to the bonding wire 620. The third trench T3 may be formed in a stepped shape.

Referring to FIG. 8, a depth in the third direction Z of a fourth trench T4 may increase gradually as the fourth trench extends toward the center area of the substrate 100 adjacent to the bonding wire 620. The fourth trench T4 may be formed in an inclined manner. In this case, unlike FIG. 5 to FIG. 7, a sidewall of the fourth trench T4 may not be parallel to the third direction Z.

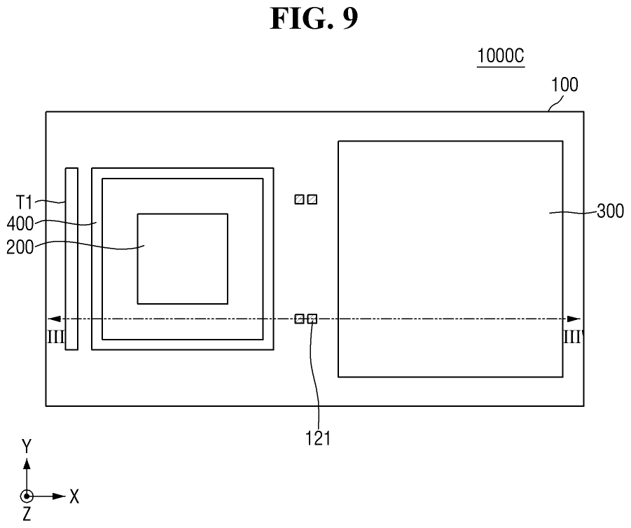

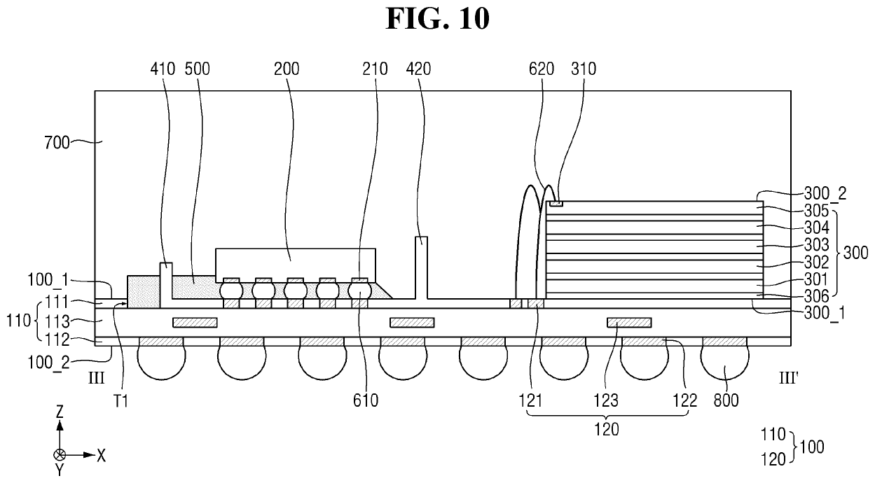

FIG. 9 is an example layout diagram illustrating a semiconductor package according to some embodiments of the present disclosure. FIG. 10 is a cross-sectional view of the semiconductor package taken along the line III-III′ in FIG. 9. For convenience of description, following descriptions focus on differences thereof from the semiconductor packages as described above using FIG. 1 to FIG. 8.

Referring to FIG. 9 and FIG. 10, the underfill material layer 500 may be formed to the first trench T1 and may be formed to contact the dam structure 400.

The first trench T1 may extend from the first surface 100_1 of the substrate 100 into at least a portion of the substrate 100. The dam structure 400 may include the first and second dam structures 410 and 420 which are spaced apart from each other while being disposed on the first surface 100_1 of the substrate. The underfill material layer 500 may be disposed within the first trench T1 and reside between the first surface 100_1 of the substrate 100 and the first semiconductor chip 200.

According to some embodiments, forming the first and second dam structures 410 and 420 having different shapes on the substrate 100 and forming the trench T1 in the substrate 100 may allow for overflow of the underfill material layer 500 to be more effectively controlled. In other words, forming the first dam structure 410 and the first trench T1 may more effectively prevent the underfill material layer 500 from being exposed outside of the semiconductor package. Furthermore, forming the second dam structure 420 with a greater height (i.e., than the first dam structure 410) may help to guide the underfill material layer 500 in the opposite direction from the area where the bonding wire 620 is formed. Accordingly, contamination of the first wiring 121 and the lower portion of the second semiconductor chip 300 may be prevented.

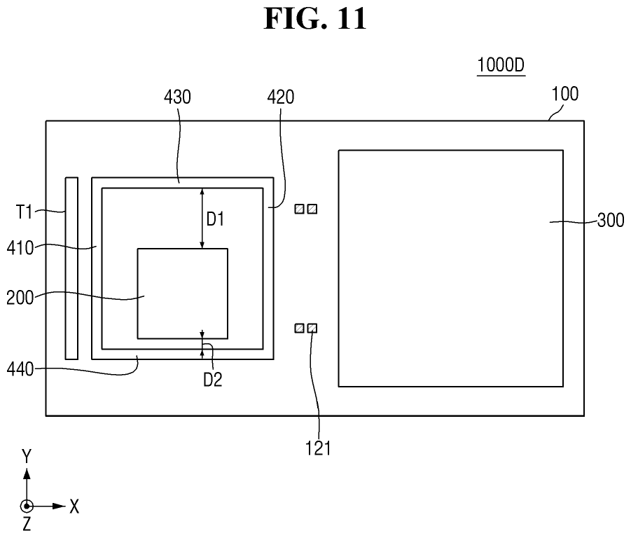

FIG. 11 to FIG. 15 are example layout diagrams illustrating a semiconductor package according to some embodiments of the present disclosure. For convenience of description, following description focuses on differences thereof from the semiconductor packages as described above using FIG. 1 to FIG. 10.

The dam structure 400 may be formed in various configurations as shown in FIG. 11 to FIG. 15.

Referring to FIG. 11, a distance D1 in the second direction Y between the third dam structure 430 and the first semiconductor chip 200 may be different from a distance D2 in the second direction Y between the fourth dam structure 440 and the first semiconductor chip 200. For example, the distance D1 between the third dam structure 430 and the first semiconductor chip 200 may be greater than the distance D2 between the fourth dam structure 440 and the first semiconductor chip 200. However, the scope of the present disclosure is not limited thereto.

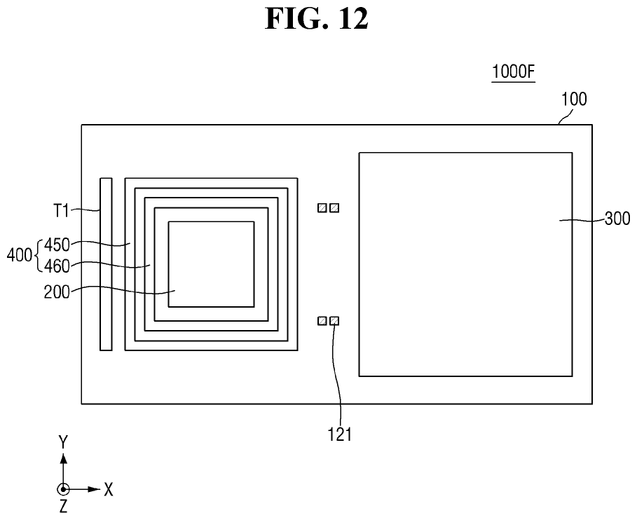

Referring to FIG. 12, the dam structure 400 may include multiple dam patterns 450 and 460 surrounding the first semiconductor chip 200.

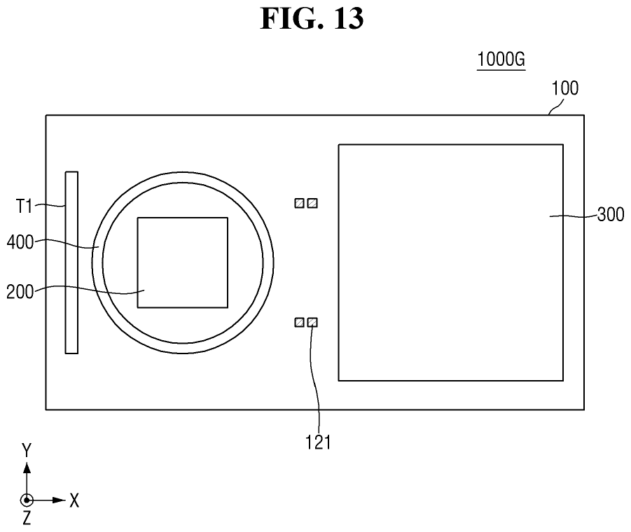

Referring to FIG. 13, the dam structure 400 may be formed in a circular shape surrounding the first semiconductor chip 200.

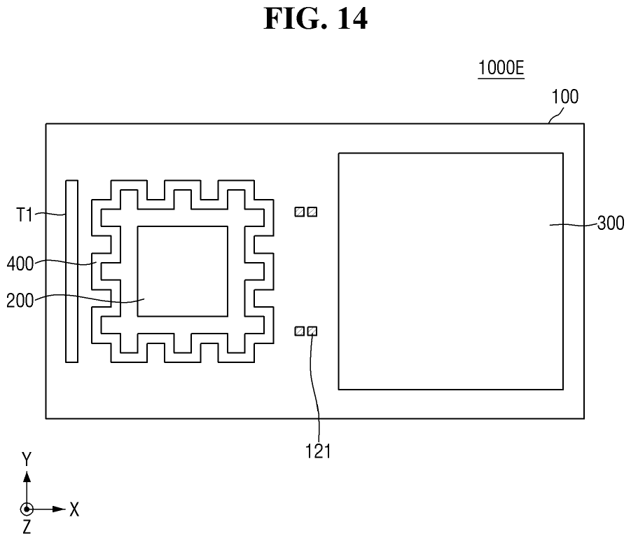

Referring to FIG. 14, the dam structure 400 may be formed into a straightly bent shape surrounding the first semiconductor chip 200.

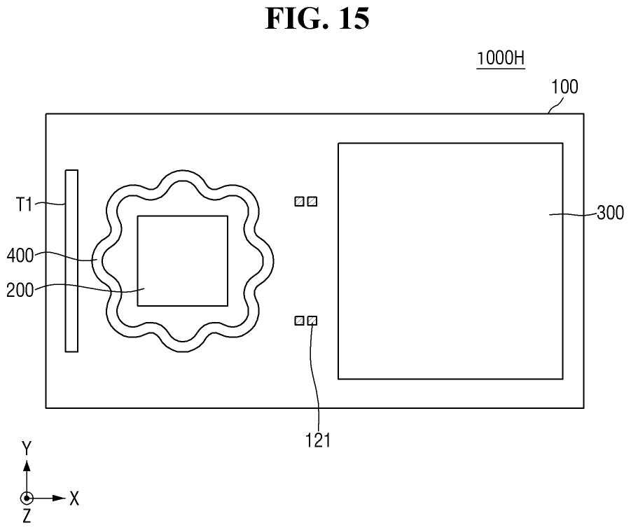

Referring to FIG. 15, the dam structure 400 may be formed in a curvedly bent shape surrounding the first semiconductor chip 200.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor package comprising:
a substrate comprising first and second surfaces opposite to each other, wherein the substrate extends in first and second directions intersecting each other;
a first semiconductor chip on the first surface of the substrate;
a second semiconductor chip on the first surface of the substrate and spaced apart from the first semiconductor chip in the first direction; and
a dam structure at least partially surrounding the first semiconductor chip,
wherein the dam structure comprises first and second dam structures on the first surface of the substrate and spaced apart from each other in the first direction such that the first semiconductor chip resides therebetween, and wherein the first and second dam structures have different heights relative to the first surface of the substrate.

2. The semiconductor package of claim 1, wherein the first dam structure has a first height relative to the first surface of the substrate,
wherein the second dam structure has a second height relative to the first surface of the substrate, wherein the second height is greater than the first height, and wherein the second dam structure is between the first semiconductor chip and the second semiconductor chip.

3. The semiconductor package of claim 1, wherein in a plan view of the semiconductor package, the dam structure extends to entirely surround the first semiconductor chip.

4. The semiconductor package of claim 1, wherein the first and second dam structures are integral with the substrate.

5. The semiconductor package of claim 1, wherein the dam structure further comprises third and fourth dam structures connecting the first and second dam structures to each other in a plan view of the semiconductor package,
wherein a distance in the second direction between the third dam structure and the first semiconductor chip is different from a distance in the second direction between the fourth dam structure and the first semiconductor chip.

6. The semiconductor package of claim 1, further comprising an underfill material layer is confined between the first surface of the substrate and the first semiconductor chip.

7. The semiconductor package of claim 6, wherein the underfill material layer resides between the first and second dam structures.

8. The semiconductor package of claim 6, wherein the underfill material layer resides in a first trench extending from the first surface of the substrate into a portion of the substrate.

9. The semiconductor package of claim 6, wherein the underfill material layer is in contact with the first dam structure and is spaced apart from the second dam structure.

10. The semiconductor package of claim 1, wherein the first semiconductor chip comprises a third surface facing the first surface of the substrate, and a fourth surface opposite to the third surface,
wherein the second semiconductor chip comprises a fifth surface facing the first surface of the substrate, and a sixth surface opposite to the fifth surface,
wherein the first semiconductor chip is electrically connected to the substrate via a first semiconductor chip pad on the third surface of the first semiconductor chip and a bump residing between the first semiconductor chip and the first surface of the substrate,
wherein the second semiconductor chip is electrically connected to the substrate via a second semiconductor chip pad on the fifth surface of the second semiconductor chip and a bonding wire connected to the second semiconductor chip pad.

11. A semiconductor package comprising:
a substrate comprising first and second surfaces opposite to each other, wherein the substrate extends in first and second directions intersecting each other;
a semiconductor chip on the first surface of the substrate;
a semiconductor chip stack comprising a plurality of semiconductor chips on the first surface of the substrate, wherein the semiconductor chip stack is spaced apart from the semiconductor chip in the first direction;
a bump electrically connecting the substrate and the semiconductor chip to each other;
a bonding wire electrically connecting the substrate and the semiconductor chip stack to each other; and
a dam structure on the first surface of the substrate, wherein the dam structure comprises portions spaced apart from each other, each portion having a height relative to the first surface of the substrate,
wherein the height of a second portion of the dam structure on a central area of the substrate adjacent to the bonding wire is greater than the height of a first portion of the dam structure on a peripheral area of the substrate.

12. The semiconductor package of claim 11, wherein the dam structure comprises a first dam structure on the peripheral area of the substrate, and a second dam structure on the central area of the substrate,
wherein the first dam structure has a first height relative to the first surface of the substrate,
wherein the second dam structure has a second height relative to the first surface of the substrate, wherein the second height is greater than the first height.

13. The semiconductor package of claim 11, wherein in a plan view of the semiconductor package, the dam structure extends to entirely surround the semiconductor chip.

14. The semiconductor package of claim 12, wherein the dam structure comprises an insulating material.

15. The semiconductor package of claim 14, further comprising an underfill material layer residing between the first surface of the substrate and the semiconductor chip, and at least partially surrounds the bump.

16. The semiconductor package of claim 15, wherein the underfill material layer is confined between the first and second dam structures.

17. The semiconductor package of claim 15, wherein the underfill material layer resides in a first trench extending from the first surface of the substrate into a portion of the substrate.

18. The semiconductor package of claim 17, wherein a depth of the first trench increases as the first trench extends toward the bonding wire.

19. A semiconductor package comprising:
a substrate comprising first and second surfaces opposite to each other, wherein a first trench extends into a portion of the substrate from the first surface;
a semiconductor chip on the first surface of the substrate;
a semiconductor chip stack comprising a plurality of semiconductor chips on the first surface of the substrate, wherein the semiconductor chip stack is spaced apart from the semiconductor chip;
a bump electrically connecting the substrate and the semiconductor chip to each other;
a bonding wire electrically connecting the substrate and the semiconductor chip stack to each other;
a dam structure on the first surface of the substrate, wherein the dam structure comprises portions spaced apart from each other; and
an underfill material layer extending between the first surface of the substrate and the semiconductor chip, and extending in the first trench.

20. The semiconductor package of claim 19, wherein a height of a portion of the dam structure residing on a central area of the substrate adjacent to the bonding wire is greater than a height of a portion of the dam structure residing on a peripheral area of the substrate.
